(19) United States
(12) Patent Application Publication
(10) Pub. No.: US 2007/0126683 A1
(43) Pub. Date: Jun. 7, 2007

(54) Display device and driving method therefor

(75) Inventors: Si-Duk Sung, Seoul (KR); Nam-Deog Kim, Yongin-si (KR); Kyong-Tae Park, Uijeongbu-si (KR); Young-Soo Yoon, Suwon-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/634,726

(22) Filed: Dec. 5, 2006

(30) Foreign Application Priority Data
Dec. 6, 2005 (KR) 10-2005-0118227

(51) Int. Cl. G09G 3/36

(52) U.S. Cl. 345/92

(57) ABSTRACT

A display device having light-emitting pixels, a driving transistor that supplies a current to the light-emitting pixels, a switching transistor that is connected to the driving transistor and selectively transmits a data voltage, and a first capacitor that turns off the driving transistor according to a voltage signal. A capacitor that adjusts a voltage of a control terminal of a driving transistor is provided, thereby performing impulsive driving.

### CROSS-REFERENCE TO RELATED APPLICATION

This application claims priority to and the benefit of Korean Patent Application No. 10-2005-0118227 filed in the Korean Intellectual Property Office on Dec. 06, 2005, the entire contents of which are incorporated herein by reference.

### FIELD OF THE INVENTION

The present invention relates to a display device and a driving method therefor.

### DESCRIPTION OF THE RELATED ART

In recent years, light-weight and thin personal computers and televisions have led to the requirement of light-weight and thin display devices so that flat panel displays are being substituted for cathode ray tubes. Flat panel displays include liquid crystal display (LCD), field emission display (FED), organic light emitting diode (OLED) display, plasma display panel (PDP) device, etc.

Generally, an active matrix type flat panel display has a matrix of pixels that display images by controlling light emission from the pixels. The pixels of an organic light emitting diode (OLED) display employ a fluorescent organic material having low power consumption, a wide viewing angle and rapid response speed suitable for displaying motion pictures. Thin film transistors that drive the pixels are classified as polysilicon thin film transistors, amorphous silicon thin film transistors, and so on according to the kind of active layer. The organic light emitting diode (OLED) display using the polysilicon thin film transistor is widely used, but its manufacturing process of is complex and costly and large screens have not be achievable. On the other hand, large screens are achievable using organic light emitting diode (OLED) display having amorphous silicon thin film transistors that have a comparatively simple manufacturing process but which suffer from bias stress stability, i.e., decreasing output current over time resulting from the use of dc control voltages. Further, since the organic light emitting diode (OLED) tends to retain an image, the display of a motion picture may cause blurring at edge of an object. In order to prevent such blurring it has been proposed to insert a black image for a predetermined period in each frame. However, when the black image is inserted for the predetermined period in one frame, luminance is degraded. Further, when a Double Data Rate (DDR) memory is used in order to increase frame frequency, costs are increased. In addition, when a separate transistor for applying a black voltage is provided in a pixel, an aperture ratio decreases.

### SUMMARY OF THE INVENTION

The present invention has been made in an effort to provide an organic light emitting diode (OLED) display, having the advantages of securing luminance and aperture ratio while performing impulsive driving in order to prevent a blurring phenomenon. An exemplary embodiment of the present invention provides a display device having light-emitting pixels, a driving transistor that supplies current to the light-emitting pixels causing them to emit light, a switching transistor that is connected to the driving transistor and selectively transmits a data voltage to the control electode of the driving transistor, and a first capacitor connected to the control electrode of the driving transistor that turns off the driving transistor according to a voltage signal provided during a blanking period of the vertical synchronization signal.

The present invention provides a display device including: a substrate; scanning signal lines that are formed on the substrate; voltage signal lines that are formed on the substrate and are separated from the scanning signal lines; an insulating layer that is formed on the scanning signal lines and the voltage signal lines; data lines that are formed on the insulating layer; driving voltage lines that are formed on the insulating layer and are separated from the data lines; switching transistors that are correspondingly connected to the scanning signal lines and the data lines; driving transistors that are correspondingly connected to the switching transistors and the driving voltage lines; pixel electrodes that are correspondingly connected to the driving transistors; and conductors that are correspondingly electrically connected to the driving transistors and overlap the voltage signal lines. The voltage signal lines may be arranged in parallel with the scanning signal lines, and the driving voltage lines may be arranged in parallel with the data lines.

Each of the driving transistors may include: a gate electrode that is electrically connected to a corresponding one of the conductors; a semiconductor that is formed on the insulating layer and is positioned on the gate electrode; a source electrode that is formed on the semiconductor and is connected to a corresponding one of the driving voltage lines; and a drain electrode that faces the source electrode and is connected to a corresponding one of the pixel electrodes.

The voltage signal lines may be positioned on the same layer as the gate electrode and may be formed of the same material as the gate electrode. The conductors may be positioned on the same layer as the source electrode and may be formed of the same material as the source electrode.

### BRIEF DESCRIPTION OF THE DRAWINGS

The foregoing and other objects, features and advantages of the present invention may become more apparent from a reading of the ensuing description together with the drawing, in which:

FIG. 1 is a block diagram of an organic light emitting diode (OLED) display according to an exemplary embodiment of the present invention.

FIG. 2 is an equivalent circuit diagram of one pixel of an organic light emitting diode (OLED) display according to an exemplary embodiment of the present invention.

FIG. 3 is a layout view of an organic light emitting diode (OLED) display according to an exemplary embodiment of the present invention.

FIGS. 4 and 5 are cross-sectional views of an organic light emitting diode (OLED) display shown in FIG. 3 taken along the lines IV-IV and V-V, respectively.

FIG. 6 is a schematic diagram of an organic light emitting device according to an exemplary embodiment of the present invention.

FIG. 7 is a signal waveform chart illustrating an operation of an organic light emitting diode (OLED) display according to an exemplary embodiment of the present invention.

FIG. 8 is a signal waveform chart illustrating another operation of an organic light emitting diode (OLED) display according to an exemplary embodiment of the present invention.

FIG. 9A is a waveform chart showing a simulation result of a voltage of a control terminal of a driving transistor in an organic light emitting diode (OLED) display according to an exemplary embodiment of the present invention.

FIG. 9B is a waveform chart showing a simulation result of a driving current of an organic light emitting diode (OLED) display according to an exemplary embodiment of the present invention.

### DETAILED DESCRIPTION OF THE EMBODIMENTS

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

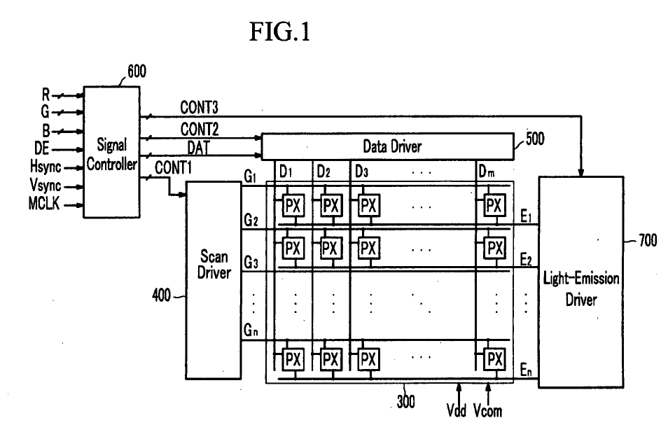

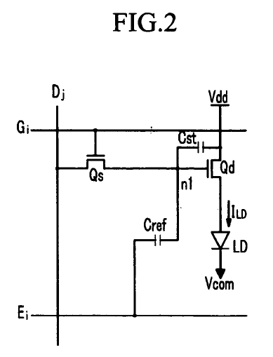

FIG. 1 is a block diagram of an organic light emitting diode (OLED) display according to an exemplary embodiment of the present invention, and FIG. 2 is an equivalent circuit diagram of one pixel in an organic light emitting diode (OLED) display according to an exemplary embodiment of the present invention.

Referring to FIG. 1, an organic light emitting diode (OLED) display according to an exemplary embodiment of the present invention includes: a display panel 300; a scan driver 400, a data driver 500, and a light-emission driver 700 that are connected to the display panel 300; and a signal controller 600 that controls scan driver 400, the data driver 500, and light-emission driver 700.

Referring to the equivalent circuit shown in FIG. 2, the display panel 300 includes a plurality of scanning signal lines G₁ to Gₙ that transmit scanning signals, a plurality of light-emission signal lines E₁ to Eₙ that transmit light-emission signals, and data lines D₁ to Dₘ that transmit data signals. Scanning signal lines G1 to Gₙ substantially extend in a row direction in parallel with one another and are separated from one another, and the light-emission signal lines E₁ to Eₙ substantially extend in a row direction in parallel with one another. Data lines D₁ to Dₘ substantially extend in a column direction in parallel with one another. Each of the voltage lines (not shown) transmit a driving voltage Vdd and a common voltage Vcom.

Referring to FIG. 2, each of the pixels PX of the organic light emitting diode (OLED) display according to the exemplary embodiment of the present invention, for example, a pixel PX that is connected to a scanning signal line Gᵢ (where i=1, 2, . . . , n) and a data line Dⱼ (where j=1, 2, . . . , m) includes an organic light emitting device LD, a driving transistor Qd, a capacitor Cst, a capacitor Cref, and a switching transistor Qs.

Driving transistor Qd has an input terminal that is connected to the driving voltage Vdd, an output terminal that is connected to an anode of organic light emitting device LD, and a control terminal n1 that is connected to an output terminal of switching transistor Qs. If a data voltage Vdat is supplied to control terminal n1 through switching transistor Qs, driving transistor Qd supplies a driving current I_{LD} corresponding to data voltage Vdat to organic light emitting device LD.

Organic light emitting device LD is a light emitting diode (LED) having a light-emission layer and an anode that is connected to the output terminal of driving transistor Qd, and a cathode that is connected to the common voltage Vcom. Organic light emitting device LD receives the driving current I_{LD} from driving transistor Qd and emits predetermined light.

Capacitor Cst is connected between the control terminal n1 and the input terminal of driving transistor Qd, and accumulates charges corresponding to the difference between the data voltage Vdat supplied through switching transistor Qs and the driving voltage Vdd.

Capacitor Cref is connected between the control terminal n1 of driving transistor Qd and the light-emission signal line Ei, and changes the voltage of the control terminal n1 of driving transistor Qd according to the light-emission signal supplied through the light-emission signal line Ei.

Switching transistor Qs has an input terminal that is connected to data line Dj, an output terminal that is connected to the control terminal n1 of driving transistor Qd, and a control terminal that is connected to the scanning signal line Gi. Switching transistor Qs is turned on by the scanning signal supplied through the scanning signal line Gi and transmits the data voltage Vdat to the control terminal n1 of driving transistor Qd.

Switching transistor Qs and driving transistor Qd are n-channel Metal Oxide Semiconductor Field Effect Transistors (MOSFETs) formed of amorphous silicon or polysilicon. However, transistors Qs and Qd may be p-channel MOSFETs. In this case, since the p-channel MOSFET and the n-channel MOSFET are complementary, the operation and the voltage and current of the p-channel MOSFET are opposite to those of the n-channel MOSFET.

The structure of the organic light emitting diode (OLED) display will now be described in detail.

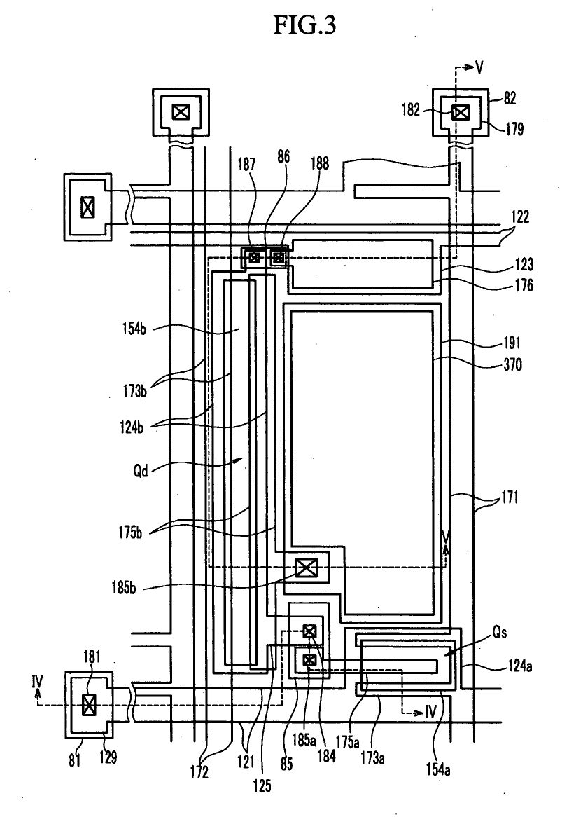

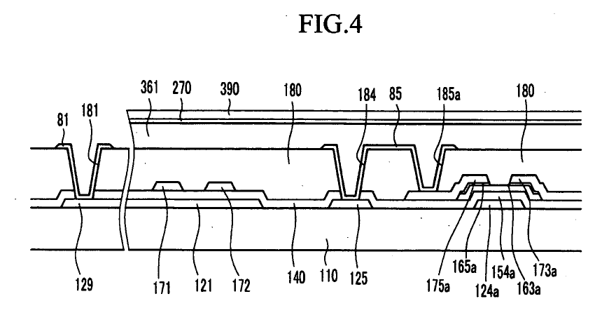

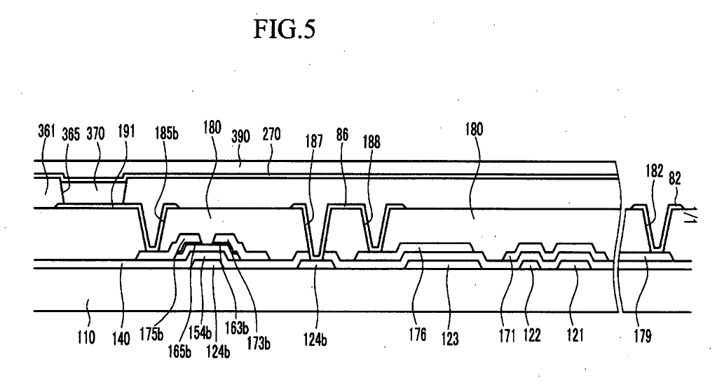

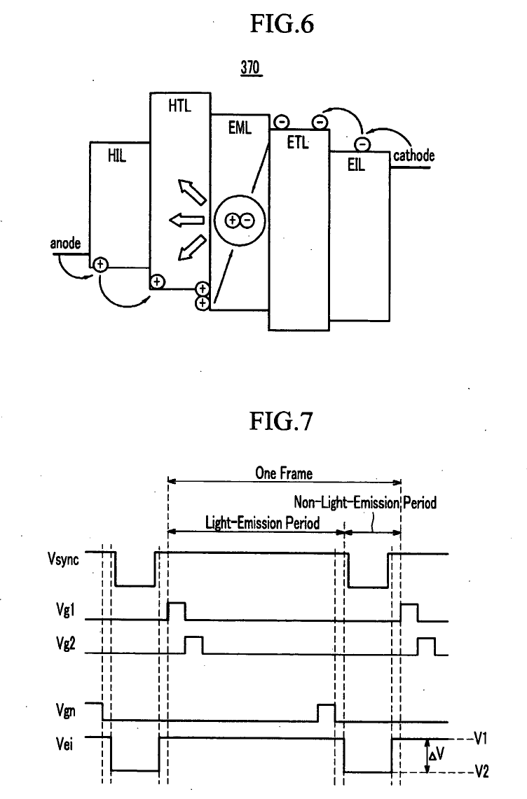

FIG. 3 is a layout view of the organic light emitting diode (OLED) display according to the exemplary embodiment of the present invention, and FIGS. 4 and 5 are cross-sectional views of the organic light emitting diode (OLED) display shown in FIG. 3 taken along the lines IV-IV and V-V, respectively. FIG. 6 is a schematic diagram of an organic light emitting device.

A plurality of scanning signal lines 121 including first control electrodes 124a, a plurality of gate conductors having a plurality of second control electrodes 124b, and a plurality of light-emission signal lines 122 are formed on an insulation substrate 110 formed of transparent glass or plastic.

Scanning signal lines 121 transmit the scanning signals and substantially extend in a horizontal direction. Each of scanning signal lines 121 includes a wider end portion 129 for connection to a different layer or an external driving circuit. First control electrodes 124a extend upward from scanning signal lines 121. When a scan driving circuit (not shown) that generates the scanning signals is integrated on substrate 110, scanning signal lines 121 may extend and may be directly connected to the scan driving circuit. When the scan driving circuit is formed outside substrate 110, scanning signal lines 121 may be connected to pads (not shown) on substrate 110 that receive the scanning signals from the scan driving circuit.

Second control electrodes 124b are separated from scanning signal lines 121 and have a protruding portion 125 which protrudes rightward at a lower portion thereof. Second control electrodes 124b extend upward.

Light-emission signal lines 122 transmit the light-emission signals and substantially extend in a horizontal direction. Each of light-emission signal lines 122 includes a protruding portion 123 that protrudes downward.

Gate conductors 121, 124b, and 122 may be formed of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), or titanium (Ti). However, each of the gate conductors may have a multi-layered structure that includes two conductive layers (not shown) having different physical properties. Of these, one conductive layer is formed of a metal having low resistivity, such as an aluminum-based metal, a silver-based metal, or a copper-based metal, in order to reduce signal delay or voltage drop. In contrast, the other conductive layer is formed of a different material, particularly, a material having excellent physical, chemical, and electrical contact characteristics to Indium Tin Oxide (ITO) and Indium Zinc Oxide (IZO), such as, a molybdenum-based metal, chromium, titanium, or tantalum. Specific examples of the combination include a combination of a chromium lower layer and an aluminum (alloy) upper layer, and a combination of an aluminum (alloy) lower layer and a molybdenum (alloy) upper layer. The gate conductors 121, 124b, and 122 may be formed of various metals or conductors other than the above materials.

A side surface of each of the gate conductors 121, 124b, and 122 is inclined with respect to a surface of the substrate 110, and the inclination angle is preferably in a range of about 30 to 80°.

A gate insulating layer 140 formed of silicon nitride (SiNₓ) or silicon oxide (SiOₓ) is formed on the gate conductors 121, 124b, and 122.

A plurality of first semiconductor islands 154a and second semiconductor stripes 154b formed of hydrogenated amorphous silicon (simply referred to as a-Si) or polysilicon are formed on the gate insulating layer 140. The first and second semiconductors 154a and 154b are positioned on the first and second control electrodes 124a and 124b, respectively.

A plurality of pairs of first ohmic contacts 163a and 163b and a plurality of pairs of second ohmic contacts 165a and 165b are formed on the first and second semiconductors 154a and 154b, respectively. The first ohmic contacts 163a and 165a have island shapes, and the second ohmic contacts 163b and 165b have linear shapes. The first and second ohmic contacts may be formed of a material, such as n+ hydrogenated amorphous silicon, in which an n-type impurity is doped with high concentration, or silicide. The first ohmic contacts 163a and 165a are disposed on the first semiconductors 154a in pairs, and the second ohmic contacts 163b and 165b are disposed on the second semiconductors 154b in pairs.

A plurality of data conductors that include a plurality of data lines 171, a plurality of driving voltage lines 172, a plurality of first and second output electrodes 175a and 175b, and storage electrodes 176 are formed on the ohmic contacts 163a, 163b, 165a, and 165b and the gate insulating layer 140.

Data lines 171 transmit data signals and substantially extend in a vertical direction so as to cross scanning signal lines 121. Each of the data lines 171 includes a plurality of first input electrodes 173a that extend in a J shape toward the first control electrodes 124a and a wider end portion 179 for connection to a different layer or an external driving circuit. When a data driving circuit (not shown) that generates data signals is integrated on the substrate 110, the data lines 171 may extend and may be directly connected to the data driving circuit. When the data driving circuit is formed outside the substrate 110, the data lines 171 may be connected to pads (not shown) on the substrate 110 that receive the data signals from the data driving circuit.

Driving voltage lines 172 transmit the driving voltage Vdd and substantially extend in the vertical direction so as to cross scanning signal lines 121. Each of the driving voltage lines 172 includes a plurality of second input electrodes 173b that individually overlap the second control electrodes 124b.

First and second output electrodes 175a and 175b are separated from each other. Further, the first and second output electrodes 175a and 175b are separated from the data lines 171 and the driving voltage lines 172. The first output electrodes 175a are formed between the J-shaped first input electrodes 173a. The first input electrodes 173a and the first output electrodes 175a face each other with the first control electrodes 124a interposed therebetween, and the second input electrodes 173b and the second output electrodes 175b face each other with the second control electrodes 124b interposed therebetween.

Storage electrodes 176 are separated from the data lines 171 and the driving voltage lines 172, and are formed to overlap the protruding portions 123 of light-emission signal lines 122.

Data conductors 171, 172, 175a, 175b, and 176 are preferably formed of a fire-resistant metal, such as molybdenum, chromium, tantalum, titanium, or an alloy thereof. Data conductors 171, 172, 175a, 175b, and 176 may have a multi-layered structure of a conductive layer (not shown) formed of a fire-resistant metal and a low-resistance material conductive layer (not shown). Examples of the multi-layered structure include a double-layered structure of a chromium or molybdenum (alloy) lower layer and an aluminum (alloy) upper layer, or a triple-layered structure of a molybdenum (alloy) lower layer, an aluminum (alloy) intermediate layer, and a molybdenum (alloy) upper layer. However, the data conductors 171, 172, 175a, 175b, and 176 may be formed of various metals or conductors other than the above materials.

Like the gate conductors 121, 124b, and 122, data conductors 171, 172, 175a, 175b, and 176 preferably have side surfaces inclined at an inclination angle of about 30 to 80° with respect to the surface of the substrate 110.

Ohmic contacts 163a, 163b, 165a, and 165b are provided only between the underlying semiconductors 154a and 154b and the overlying data conductors 171, 172, 175a, 175b, and 176 so as to reduce contact resistance therebetween. The semiconductors 154a and 154b have exposed portions, which are not covered with the data conductors 171, 172, 175a, 175b, and 176, including portions between the input electrodes 173a and 173b and the output electrodes 175a and 175b.

A passivation layer 180 is formed on the data conductors 171, 172, 175a, 175b, and 176 and the exposed semiconductors 154a and 154b. The passivation layer 180 is formed of an inorganic insulator, such as silicon nitride or silicon oxide, an organic insulator, or a low-dielectric-constant insulator. The dielectric constant of the organic insulator and the low-dielectric-constant insulator is preferably 4.0 or less, and, for example, a-Si:C:O or a-Si:O:F that is formed by a plasma enhanced chemical vapor deposition (PECVD) method is used. The passivation layer 180 may be formed of a material having photosensitivity among the organic insulators, and a surface of the passivation layer 180 may be planarized. The passivation layer 180 may have a double-layered structure of a lower inorganic layer and an upper organic layer so as to use the excellent insulating characteristics of an organic layer and to prevent the exposed portions of the semiconductors 154a and 154b from being damaged.

A plurality of contact holes 182, 185a, 185b, and 188 are formed in the passivation layer 180 so as to expose the end portions 179 of the data lines 171, the first and second output electrodes 175b, and the storage electrodes 176, respectively. Further, a plurality of contact holes 181, 184, and 187 are formed in the passivation layer 180 and the gate insulating layer 140 so as to expose the end portions 129 of scanning signal lines 121, the second input electrodes 124b, and the second control electrodes 124b, respectively.

A plurality of pixel electrodes 191, a plurality of connecting members 85 and 86, and a plurality of contact assistants 81 and 82 are formed on the passivation layer 180. They may be formed of a reflective metal, such as aluminum, silver, or an alloy thereof.

Pixel electrodes 191 are physically and electrically connected to the second output electrodes 175b through the contact holes 185b, and the connecting members 85 are connected to the protruding portions 125 of the second control electrodes 124b and the first output electrodes 175a through the contact holes 184 and 185a. The connecting members 86 are connected to the second control electrodes 124b and storage electrodes 176 through the contact holes 187 and 188.

Contact assistants 81 and 82 are connected to the end portions 129 of scanning signal lines 121 and the end portions 179 of the data lines 171 through the contact holes 181 and 182, respectively. The contact assistants 81 and 82 assist adhesion of the end portions 179 and 129 of the data lines 171 and scanning signal lines 121 to an external device and protect the end portions 179 and 129.

A partition 361 is formed on the passivation layer 180. The partition 361 defines openings 365 by surrounding edges of the pixel electrodes 191 in a bank shape, and is formed of an organic insulator or an inorganic insulator. The partition 361 may be formed of photoresist including a black pigment. In this case, the partition 361 serves as a light blocking member. A process of forming the partition 361 is simply performed.

Organic light emitting members 370 are formed in the openings 365 on the pixel electrodes 191 defined by the partition 361. The organic light emitting members 370 are formed of an organic material that uniquely emits light of one of three primary colors, such as red, green, and blue. The organic light emitting diode (OLED) display displays desired images by a spatial sum of color light components of primary colors emitted by the organic light emitting members 370.

As in FIG. 6, the organic light emitting members 370 may have a multi-layered structure including auxiliary layers ETL, HTL, EIL, and HIL for improving light-emission efficiency of the light-emission layer, in addition to the light-emission layer EML. The auxiliary layers include an electron transport layer ETL and a hole transport layer HTL for balancing electrons and holes, and an electron injection layer EIL and a hole injection layer HIL for reinforcing the injection of the electrons and holes.

A common electrode 270 is formed on the organic light emitting members 370. The common electrode 270 is applied with the common voltage Vcom and is formed of a transparent conductive material, such as ITO or IZO.

In the organic light emitting diode (OLED) display, a first control electrode 124a connected to a scanning signal line 121, a first input electrode 173a connected to a data line 171, and a first output electrode 175a form a switching thin film transistor Qs, together with a first semiconductor 154a. A channel of the switching thin film transistor Qs is formed in the first semiconductor 154a between the first input electrode 173a and the first output electrode 175a. A second control electrode 124b connected to a first output electrode 175a, a second input electrode 173b formed on a driving voltage line 172, and a second output electrode 175b connected to a pixel electrode 191 form a driving thin film transistor Qd, together with a second semiconductor 154b. A channel of the driving thin film transistor Qd is formed in the second semiconductor 154b between the second input electrode 173b and the second output electrode 175b. The pixel electrodes 191, the organic light emitting members 370, and the common electrode 270 form organic light emitting device LD. Here, the pixel electrodes 191 serve as an anode, and the common electrode 270 serves as a cathode. In contrast, the pixel electrodes 191 may serve as the cathode, and the common electrode 270 may serve as the anode. A second control electrode 124b and a driving voltage line 172 that overlap each other form capacitor Cst, and a storage electrode 176 and a protruding portion 123 of a light-emission signal line 122 that overlap each other form capacitor Cref.

The organic light emitting diode (OLED) display according to the present exemplary embodiment emits light below the substrate 110 and displays the images. That is, the transparent pixel electrodes 191 and the nontransparent common electrode 270 display the images in a bottom emission type where the images are displayed below the substrate 110.

When semiconductors 154a and 154b are formed of polysilicon, an intrinsic region (not shown) facing the control electrodes 124a and 124b and an extrinsic region (not shown) on both sides of the intrinsic region are included. The extrinsic region is electrically connected to the input electrodes 173a and 173b and the output electrodes 175a and 175b, and the ohmic contacts 163a, 163b, 165a, and 165b may be omitted.

Control electrodes 124a and 124b may be disposed on the semiconductors 154a and 154b. In this case, the gate insulating layer 140 is positioned between the semiconductors 154a and 154b and the control electrodes 124a and 124b. At this time, data conductors 171, 172, 173b, 175b, and 176 may be positioned on the gate insulating layer 140 and may be electrically connected to the semiconductors 154a and 154b through the contact holes (not shown) formed in gate insulating layer 140. In contrast, data conductors 171, 172, 173b, 175b, and 176 may be disposed below semiconductors 154a and 154b and may be electrically connected to the overlying semiconductors 154a and 154b.

A sealing member 390 is formed on the common electrode 270. The sealing member 390 seals the organic light emitting members 370 and the common electrode 270 so as to prevent moisture and/or oxygen from infiltrating from the outside. The sealing member 390 may be formed of a material similar to the substrate 110, such as an insulating material of glass or plastic.

Returning to FIG. 1, scan driver 400 is connected to scanning signal lines G1 to Gₙ of the display panel 300 and applies the scanning signals Vg₁ to Vgₙ, which are obtained by combining a high voltage Von and a low voltage Voff for turning on and off the switching transistors Qs, to scanning signal lines G1 to Gₙ.

Data driver 500 is connected to data lines D₁ to Dₘ of display panel 300 and applies the data voltage Vdat representing the image signals to the data lines.

Light-emission driver 700 is connected to light-emission signal lines E₁ to Eₙ of display panel 300 and applies light-emission signals Ve₁ to Veₙ, which are obtained by combining a first voltage V1 and a second voltage V2 having different levels, to the light-emission signal lines.

Scan driver 400, data driver 500, and light-emission driver 700 may be directly mounted on display panel 300 as a plurality of driver IC chips, or may be mounted on a flexible printed circuit film (not shown) and may be attached to the display panel through a TCP (Tape Carrier Package). Alternatively, scan driver 400, data driver 500, or light-emission driver 700 may be formed on display panel 300, together with the signal lines and transistors, thereby implementing an SOP (System On Panel). Signal controller 600 controls operations of scan driver 400, data driver 500, and light-emission driver 700.

Hereinafter, the operation of the organic light emitting diode (OLED) display will be described.

FIG. 7 is a waveform chart illustrating the operation of the organic light emitting diode (OLED) display according to an exemplary embodiment of the present invention.

Referring to FIGS. 1 and 7, signal controller 600 receives input image signals R, G, and B and input control signals, a vertical synchronization signal Vsync, a horizontal synchronization signal Hsync, a main clock MCLK, and a data enable signal DE from an external graphic controller (not shown). Signal controller 600 appropriately processes the image signals R, G, and B on the basis of the input control signals according to the operation conditions of display panel 300 and generates scan control signal CONT1, data control signal CONT2, and light-emission control signal CONT3. Signal controller 600 transmits the scan control signal CONT1 to scan driver 400, transmits the data control signal CONT2 and the processed image signal DAT to the data driver 500, and transmits the light-emission control signal CONT3 to light-emission driver 700.

The scan control signal CONT1 includes a scanning start signal STV for instructing the start of scanning high voltage Von and at least one clock signal for controlling the output of the high voltage Von. The scan control signal CONT1 may further include an output enable signal OE for defining the duration of the high voltage Von.

The data control signal CONT2 includes a horizontal synchronization start signal STH for informing data transmission of one row of pixels and a load signal LOAD for instructing to apply the data voltage Vdat to the data lines D₁ to Dₘ, and a data clock signal HCLK.

First, data driver 500 sequentially receives image data DAT for one row of pixels PX according to the data control signal CONT2 from signal controller 600, and applies an analog data voltage Vdat corresponding to each image data DAT to the corresponding data line.

Scan driver 400 receives the scanning start signal STV and the clock signal supplied from signal controller 600, and outputs the scanning signal Vgᵢ having the high voltage Von for one cycle of the clock. Scan driver 400 may include a shift register that receives the previous scanning signal, shifts the received scanning signal by one cycle of the clock, and outputs the shifted scanning signal.

If the scanning signal Vgᵢ is the high voltage Von supplied from scan driver 400, switching transistor Qs is turned on, and the data voltage Vdat is applied to the control terminal n1 of driving transistor Qd through switching transistor Qs. Therefore, a predetermined driving current I_{LD} flows into organic light emitting device LD through the output terminal of driving transistor Qd, and organic light emitting device LD emits light corresponding to the supplied driving current I_{LD}.

During such a light-emission operation, the light-emission signal Veᵢ that is applied to capacitor Cref through the light-emission signal line Ei has a first voltage (V1) level. Therefore, capacitor Cst accumulates charges corresponding to the difference between the data voltage Vdat and the driving voltage Vdd, and the capacitor Cref accumulates charges corresponding to the difference between the first voltage V1 and the data voltage Vdat.

The above operation is sequentially performed up to the pixels PX of the n-th row, thereby displaying one image.

Next, if the vertical synchronization signal Vsync is changed to a low voltage level, the light-emission signal Veᵢ from light-emission driver 700 is changed to a second voltage (V2) level. When the vertical synchronization signal Vsync has the low voltage level, that is, during a blanking period of the vertical synchronization signal Vsync, the light-emission signal Veᵢ presents the second voltage (V2) level. If the light-emission signal Veᵢ having the second voltage (V2) level is supplied to the capacitor Cref, the voltage of the control terminal n1 of driving transistor Qd is changed. That is, the capacitor Cst and the capacitor Cref are coupled with each other according to the change of the light-emission signal Veᵢ, and the voltage of the control terminal n1 of driving transistor Qd, which is a voltage between the capacitor Cst and the capacitor Cref, is changed as expressed by the following expression.

$$Vdat 2 = Vdat 1 - Cref \frac{Δ V}{( Cst + Cref )}$$

At this time, Vdat1 represents a voltage of the control terminal n1 of driving transistor Qd when the light-emission signal Veᵢ is the first voltage (V1) level, and Vdat2 represents a voltage of the control terminal n1 of driving transistor Qd when the light-emission signal Veᵢ is the second voltage (V2) level. Further, Cst represents capacitance of the capacitor Cst and Cref represents capacitance of the capacitor Cref. In addition, ΔV represents the difference between the first voltage V1 and the second voltage V2 of the light-emission signal Veᵢ.

As the voltage level of the light-emission signal Veᵢ decreases, the voltage of the control terminal n1 of driving transistor Qd is made lower than the threshold voltage of driving transistor Qd, and then driving transistor Qd does not output the driving current I_{LD}. Therefore, since organic light emitting device LD does not emit light, the pixel PX displays black.

The light-emission signal Veᵢ is simultaneously changed to the second voltage (V2) level for all the pixel rows, and thus the display panel 300 displays black during the blanking period of the vertical synchronization signal Vsync. At this time, the time at which the light-emission signal Veᵢ presents the second voltage (V2) level may be the blanking period of the vertical synchronization signal Vsync, or a back or front porch of the blanking period.

Next, if the light-emission signal Veᵢ is changed to the first voltage (V1) level again, the voltage of the control terminal n1 of driving transistor Qd has the value of the data voltage Vdat before black display according to coupling of the capacitor Cst and the capacitor Cref. Accordingly, driving transistor Qd outputs the driving current I_{LD} corresponding to the data voltage Vdat again, and organic light emitting device LD emits predetermined light according to the driving current I_{LD}. Therefore, the pixel PX displays a color before black display again until the scanning signal Vgᵢ of the next frame is applied.

As a result, the organic light emitting diode (OLED) display displays black during the blanking period of the vertical synchronization signal Vsync, thereby securing a sufficient light-emission time and having an impulsive effect.

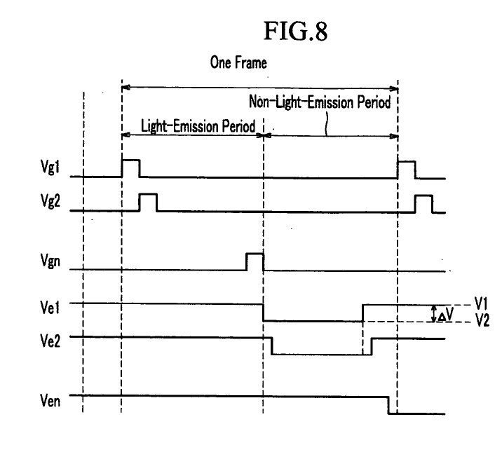

FIG. 8 is a waveform chart illustrating another operation of the organic light emitting diode (OLED) display according to an exemplary embodiment of the present invention.

Referring to FIG. 8, signal controller 600 receives input image signals R, G, and B and input control signals for controlling the display of the image signals R, G, and B, and generates a scan control signal CONT1, a data control signal CONT2, and a light-emission control signal CONT3. Signal controller 600 transmits the scan control signal CONT1 to scan driver 400, transmits the data control signal CONT2 and the processed image signal DAT to the data driver 500, and transmits the light-emission control signal CONT3 to light-emission driver 700.

Data driver 500 sequentially receives image data for the pixels PX according to the data control signal CONT2 from signal controller 600, and applies an analog data voltage Vdat corresponding to each image data to the corresponding data line Dj.

Scan driver 400 receives the scanning start signal STV and the clock signal supplied from signal controller 600, and outputs the scanning signal Vgᵢ having a high voltage Von for one cycle of the clock.

If the scanning signal Vgᵢ of the high voltage Von is supplied from scan driver 400, switching transistor Qs is turned on, and the data voltage Vdat is applied to the capacitor Cst and the control terminal n1 of driving transistor Qd through switching transistor Qs. Driving transistor Qd outputs a predetermined driving current I_{LD} to organic light emitting device LD according to the data voltage Vdat. Therefore, organic light emitting device LD emits light corresponding to the supplied driving current I_{LD}.

At this time, light-emission driver 700 applies the light-emission signal Veᵢ of the first voltage (V1) level to the capacitor Cref. Then, the capacitor Cst accumulates charges corresponding to a difference between the data voltage Vdat and the driving voltage Vdd, and the capacitor Cref accumulates charges corresponding to a difference between the first voltage V1 and the data voltage Vdat. The above operation is sequentially performed up to the pixels PX of the n-th row, thereby displaying one image.

Next, light-emission driver 700 receives the light-emission control signal CONT3, and sequentially changes the light-emission signal Veᵢ having the first voltage signal (V1) level to the second voltage signal (V2) level. The capacitor Cref receives the light-emission signal Veᵢ of the second voltage (V2) level, and decreases the voltage of the control terminal n1 of driving transistor Qd through coupling with the capacitor Cst. If the voltage of the control terminal n1 of driving transistor Qd becomes lower than a threshold voltage of driving transistor Qd, driving transistor Qd does not output the driving current I_{LD}, and thus organic light emitting device LD does not emit light. Therefore, the pixel PX displays black until the light-emission signal Veᵢ is changed to the first voltage (V1) level again.

The light-emission signal Veᵢ is changed to the first voltage (V1) level before the scanning signal Vgᵢ of the high voltage Von of the next frame is supplied. Therefore, in the state where the light-emission signal Veᵢ of the first voltage (V1) level is applied to the capacitor Cref, the data voltage Vdat of the next frame is supplied.

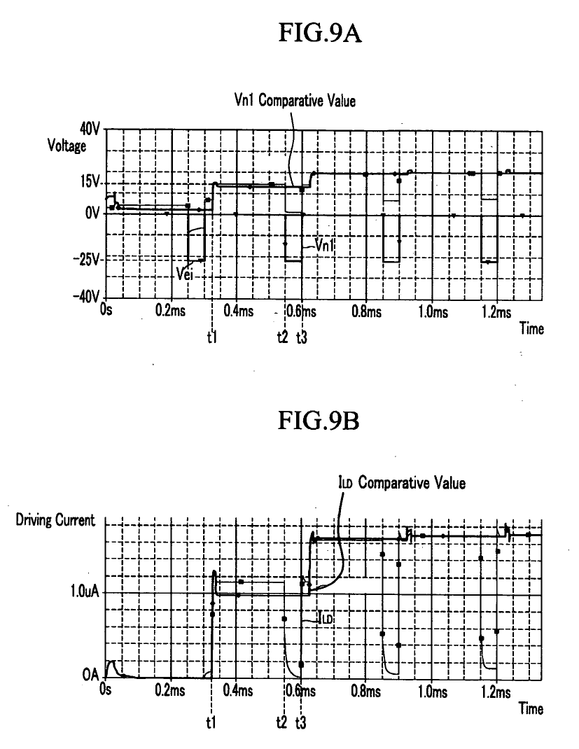

FIGS. 9A and 9B are waveform charts showing a simulation result of a voltage of the control terminal n1 of driving transistor Qd and a driving current I_{LD} in the organic light emitting diode (OLED) display according to an exemplary embodiment of the present invention.

FIG. 9A shows time-variant graphs of the light-emission signal Veᵢ, the voltage Vₙ₁ of the control terminal n1 of driving transistor Qd in the organic light emitting diode (OLED) display according to an exemplary embodiment of the present invention and, Vₙ₁ Comparative Value, while FIG. 9B shows time-variant graphs of the driving current I_{LD} in the organic light emitting diode (OLED) display according to an exemplary embodiment of the present invention and I_{LD} Comparative Value.

In an exemplary embodiment of the present invention, the comparative values refer to the voltage of control terminal n1 of driving transistor Qd and the driving current in the organic light emitting diode (OLED) display, which includes only a driving transistor Qd, an organic light emitting device LD, a switching transistor Qs, and a capacitor Cst in one pixel, excluding a capacitor Cref connected to a light-emission signal line Ei.

In FIG. 9A, the voltage Vₙ₁ Comparative Value has a cycle of about 0.3 ms and has different voltage levels according to the data voltage Vdat supplied through switching transistor Qs. The voltage Vₙ₁ Comparative Value of the control terminal n1 of driving transistor Qd of the comparative values keeps the same voltage level until the next data voltage Vdat is supplied, and thus a constant driving current I_{LD} Comparative Value is output, as in FIG. 9B.

In the organic light emitting diode (OLED) display according to the present invention, when the light-emission signal Veᵢ is 0 V (t1), if the data voltage Vdat is applied, the voltage of the control terminal n1 of driving transistor Qd is set to about 15 V corresponding to the data voltage Vdat. Next, when the light-emission signal Veᵢ falls to about −25 V (t2), voltage Vₙ₁ of the control terminal n1 of driving transistor Qd falls to about 2 V. The fallen voltage Vₙ₁ of the control terminal n1 of driving transistor Qd stays at a voltage level of 2 V until the light-emission signal Veᵢ rises to 0 V again (t3). When the threshold voltage of driving transistor Qd is higher than 2 V, as in FIG. 9B, the driving current I_{LD} is about 0 A. Therefore, since organic light emitting device LD does not emit light, the pixel PX displays black when the light-emission signal Veᵢ keeps about −25 V (t2 to t3), and thus the impulsive effect is shown.

As described above, according to the present invention, the display device has a capacitor that adjusts the voltage of the control terminal of the driving transistor, thereby performing impulsive driving. Further, since impulsive driving is performed in only the blanking period of the vertical synchronization period, the light-emission time can be sufficiently secured, and degradation of luminance can be prevented.

While this invention has been described in connection with what is presently considered to be practical exemplary embodiments, it is to be understood that various modifications and equivalent arrangements will be apparent to those skilled in the art without, however, departing from the spirit and scope of the invention.

What is claimed is:

1. A display device having a plurality of light-emitting pixels, comprising:
a driving transistor that is connected to a driving voltage and supplies a current to the pixels;
a switching transistor that is connected to the driving transistor and selectively transmits a data voltage; and
a first capacitor that turns off the driving transistor according to a voltage signal.

2. The display device of claim 1, wherein each of the pixels further includes a second capacitor that is connected between the driving voltage and a control terminal of the driving transistor.

3. The display device of claim 2, wherein the first capacitor is connected to the control terminal of the driving transistor so as to determine a voltage of the control terminal of the driving transistor by coupling with the second capacitor according to a change in the voltage signal.

4. The display device of claim 1, wherein the voltage signal has a first voltage level and a second voltage level lower than the first voltage level.

5. The display device of claim 4, wherein, when the voltage signal is the second voltage level, the driving transistor is turned off.

6. The display device of claim 5, wherein the voltage signal has the second voltage level in a blanking period of a vertical synchronization signal.

7. The display device of claim 5, wherein the pixels are arranged in a matrix shape and the voltage signal sequentially changes to the second voltage level according to pixel rows.

8. A method of driving a display device, which includes a plurality of pixels, each of the pixels having a light-emitting device and a driving transistor supplying a current to the light-emitting device, the method comprising:
applying a data signal to the driving transistor to cause the light-emitting device to emit light; and
applying a reverse bias voltage to the driving transistor through a capacitor connected to a voltage signal.

9. The method of claim 8, wherein the voltage signal alternately has a first voltage level and a second voltage level lower than the first voltage level.

10. The method of claim 9, wherein when the voltage signal is the second voltage level, the capacitor applies the reverse bias voltage to the driving transistor.

11. The method of claim 10, wherein the applying of the reverse bias voltage is performed in a blanking period of a vertical synchronization signal.

12. A display device comprising:
a substrate;
scanning signal lines formed on the substrate;
voltage signal lines formed on the substrate and separated from the scanning signal lines;
an insulating layer formed on the scanning signal lines and the voltage signal lines;
data lines formed on the insulating layer;
driving voltage lines formed on the insulating layer and separated from the data lines;
switching transistors that are correspondingly connected to the scanning signal lines and the data lines;
driving transistors that are correspondingly connected to the switching transistors and the driving voltage lines;
pixel electrodes that are correspondingly connected to the driving transistors; and
conductors that are correspondingly electrically connected to the driving transistors and overlap the voltage signal lines.

13. The display device of claim 12, wherein the voltage signal lines are arranged in parallel with the scanning signal lines, and the driving voltage lines are arranged in parallel with the data lines.

14. The display device of claim 13, wherein each of the driving transistors includes:
a gate electrode that is electrically connected to a corresponding one of the conductors;
a semiconductor formed on the insulating layer and positioned on the gate electrode;
a source electrode formed on the semiconductor and connected to a corresponding one of the driving voltage lines; and
a drain electrode facing the source electrode and connected to a corresponding one of the pixel electrodes.

15. The display device of claim 14, wherein the voltage signal lines are positioned on the same layer as the gate electrode, and are formed of the same material as the gate electrode.

16. The display device of claim 15, wherein the conductors are positioned on the same layer as the source electrode, and are formed of the same material as the source electrode.

17. A display device having a plurality of organic light-emitting pixels, scanned during each frame, comprising:
a driving transistor for supplying an illumination current to a pixel corresponding to a data voltage during a frame;
a source of light emission voltages, said source presenting a first light emission voltage when the data voltage is present and a second voltage thereafter;
a capacitor connected between said driving transistor and said source of light emission voltages for accumulating a charge corresponding to the difference between the data voltage and the first light emission voltage, said capacitor charge turning off said transistor when said second voltage is present to provide a blanking interval between frames.

18. A display device having a plurality of light-emitting pixels, comprising:
a driving transistor for supplying a current to the pixels;
a switching transistor connected to the driving transistor for selectively transmitting a data voltage to turn on the driving transistor;
a storage capacitor connected to the driving transistor for storing the data voltage;
a reference capacitor connected to the driving transistor for turning off the driving transistor during a blanking interval,
whereby the storage capacitor turns on the driving transistor at the end of the blanking interval.
